(19) United States
(12) Patent Application Publication
(10) Pub. No.: US 2024/0196656 A1
(43) Pub. Date: Jun. 13, 2024

(54) LIGHT EMITTING DISPLAY DEVICE

(71) Applicant: LG Display Co., Ltd., Seoul (KR)

(72) Inventor: Yoon Sung KIM, Paju-si (KR)

(73) Assignee: LG Display Co., Ltd., Seoul (KR)

(21) Appl. No.: 18/225,580

(22) Filed: Jul. 24, 2023

(30) Foreign Application Priority Data
Dec. 13, 2022 (KR) 10-2022-0173764

(51) Int. Cl. H10K 59/122; H10K 59/12; H10K 59/80

(52) U.S. Cl. CPC H10K 59/122; H10K 59/1201; H10K 59/80518

(57) ABSTRACT

A light emitting display device is discussed. The light emitting display device can include a first anode and a second anode spaced apart from each other, a reflective metal between the first anode and the second anode, and a bank above the reflective metal at a non-emission area to expose an emission area of each of the first anode and the second anode. The bank can include a trench having a width gradually increasing while extending downwards toward the reflective metal. In accordance with this configuration, there is an effect of preventing leakage current from flowing between the first anode and the second anode.

### CROSS-REFERENCE TO RELATED APPLICATIONS

This application claims priority to Korean Patent Application No. 10-2022-0173764, filed in the Republic of Korea on Dec. 13, 2022, the entire contents of which are hereby expressly incorporated by reference into the present application.

### BACKGROUND

### Field

The present disclosure relates to a display device, and more particularly to a light emitting display device capable of preventing flow of leakage current between sub-pixels and a method of manufacturing the same.

### Discussion of the Related Art

With the recent advent of an information-dependent age, the field of display devices to visually display electric information signals has rapidly developed. As a result, research on enhancing aspects of various display devices such as thinness, lightness, low power consumption, etc. is being conducted.

Among the display devices, a light emitting display device can achieve lightness and thinness because the light emitting display device includes a light emitting element, which is a self-luminous element, and as such, does not require a separate light source for the light emitting element.

Such a light emitting element is configured through inclusion of an organic layer between an anode and a cathode. As an electric field is applied between the anode and the cathode, the light emitting element emits light.

In the light emitting display device, which includes the light emitting element as mentioned above, however, there can be a limitation in that a part of plural sub-pixels may emit light due to leakage current.

### SUMMARY OF THE DISCLOSURE

Accordingly, the present disclosure is directed to a light emitting display device that substantially obviates one or more problems due to limitations and disadvantages of the related art.

An object of the present disclosure is to provide a light emitting display device capable of preventing leakage current from flowing between neighboring pixels.

The light emitting display device according to an aspect of the present disclosure includes a reflective metal in a non-emission area, and a bank including a trench exposing the reflective metal. In accordance with the present disclosure, an organic layer and a cathode deposited on the bank are separated in the trench of the bank, thereby preventing leakage current from flowing between adjacent sub-pixels. The trench of the bank can be formed to include a first trench and a second trench having different shapes, through irradiation of a laser beam onto the reflective metal.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the disclosure, as embodied and broadly described herein, a light emitting display device can include a first anode and a second anode spaced apart from each other, a reflective metal between the first anode and the second anode, and a bank above the reflective metal at a non-emission area, to expose an emission area of each of the first anode and the second anode, the bank comprising a trench having a width gradually increasing while extending downwards toward the reflective metal.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1A is a plan view of a light emitting display device according to a first embodiment of the present disclosure;

FIG. 1B is an enlarged plan view of an area C1 in FIG. 1A;

FIG. 2 is a cross-sectional view taken along line I-I′ in FIG. 1A;

FIG. 3A is an enlarged view of an area A in FIG. 2;

FIG. 3B is a cross-sectional view explaining an effect of a reflective metal according to the first embodiment of the present disclosure;

FIG. 4 is a perspective view corresponding to FIGS. 3A and 3B;

FIGS. 5A to 5F are cross-sectional views of a method of manufacturing the light emitting display device according to the first embodiment of the present disclosure;

FIGS. 6A to 6C are cross-sectional views concretely showing the light emitting display device manufacturing method shown in FIG. 5B;

FIGS. 7A to 7C are plan views of areas B in FIGS. 6A to 6C, respectively;

FIGS. 8A to 8F are perspective views concretely showing the light emitting display device manufacturing method shown in FIGS. 5D and 5E;

FIGS. 9A and 9B are cross-sectional views of another embodiment of the manufacturing method shown in FIG. 6B;

FIG. 10A is a plan view of a light emitting display device according to a second embodiment of the present disclosure;

FIG. 10B is an enlarged plan view of an area C2 in FIG. 10A;

FIG. 11 is a cross-sectional view taken along line II-II′ in FIG. 10A;

FIG. 12 is a perspective view corresponding to FIG. 11; and

FIGS. 13A to 13E are cross-sectional views of a method of manufacturing the light emitting display device according to the second embodiment of the present disclosure; and

FIG. 14 is a cross-sectional view of a light emitting display device according to a third embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by the scope of claims.

The shapes, sizes, ratios, angles, numbers, and the like disclosed in the drawings for describing various embodiments of the present disclosure are merely examples, and thus, the present disclosure is not limited to the illustrated details. Like reference numerals refer to like elements throughout. In the following description, when the detailed description of the relevant known function or configuration is determined to unnecessarily obscure aspects of the present disclosure, the detailed description will be omitted.

When “comprise,” “have,” and “include” described in the present disclosure are used, another part can be added unless “only” is used. Terms in a singular form can include plural forms unless stated to the contrary.

In construing an element, the element is construed as including an error or tolerance range although there is no explicit description of such an error or tolerance range.

In describing a positional relationship, for example, when a positional relation between two parts is described as, for example, “on,” “over,” “under,” and “next,” one or more other parts can be disposed between the two parts unless a more limiting term, such as “just” or “direct(ly)” is used.

In describing a temporal relationship, for example, when the temporal order is described as, for example, “after,” “subsequent,” “next,” and “before,” a situation that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another, and may not define order. For example, a first element could be termed a second element within the scope of the present disclosure.

In the following description of the embodiments, “first horizontal axis direction,” “second horizontal axis direction” and “vertical axis direction” should not be interpreted as having only geometrical relations in which parts are perpendicular to each other, and can mean wider orientations within the ranges in which elements of the disclosure functionally work.

The term “at least one” should be understood as including all combinations presented by one or more of associated elements. For example, “at least one of a first element, a second element or a third element” may not only mean the first element, the second element or the third element, respectively, but also mean all combinations presented by two or more of the first element, the second element and the third element.

Features of various embodiments of the present disclosure can be partially or wholly coupled to or combined with each other, and can be variously inter-operated with each other and driven technically as those skilled in the art can sufficiently understand. The embodiments of the present disclosure can be carried out independently from each other, or can be carried out together in a co-dependent manner.

In the drawings, wherever possible, the same elements will be denoted by the same reference numerals throughout the drawings even though they are depicted in different drawings. Further, the elements illustrated in the accompanying drawings can have scales different from the actual scales thereof for convenience of explanation, and are thus limited by the scales illustrated in the drawings.

Hereinafter, a light emitting display device according to embodiments of the present disclosure will be described in detail with reference to the accompanying drawings. All the components of each light emitting display device according to all embodiments of the present disclosure are operatively coupled and configured.

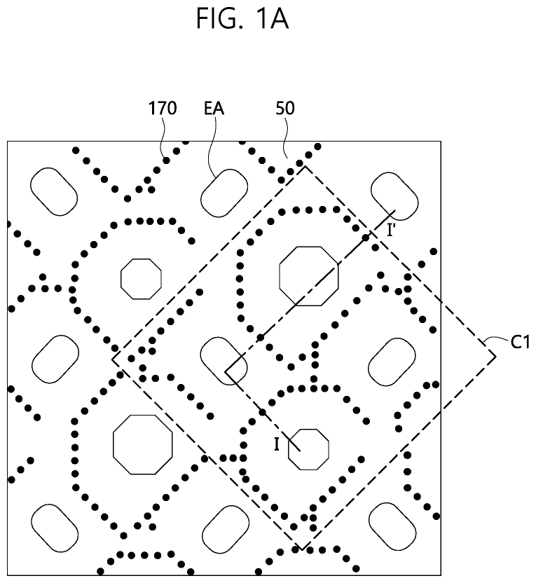

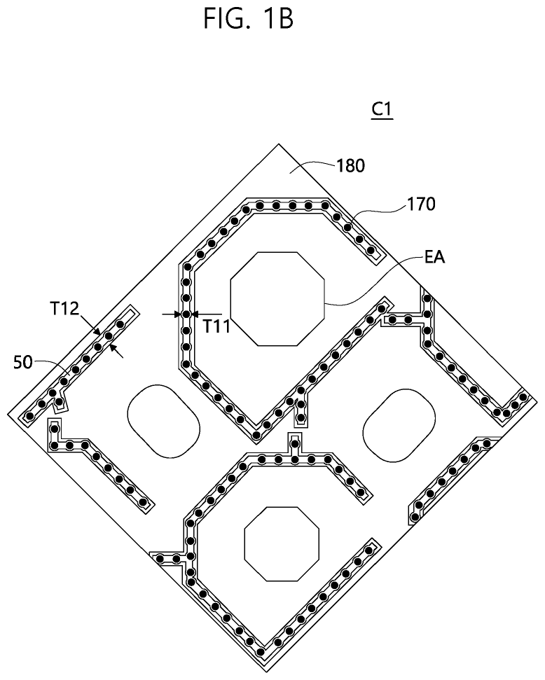

FIG. 1A is a plan view of a light emitting display device according to a first embodiment of the present disclosure.

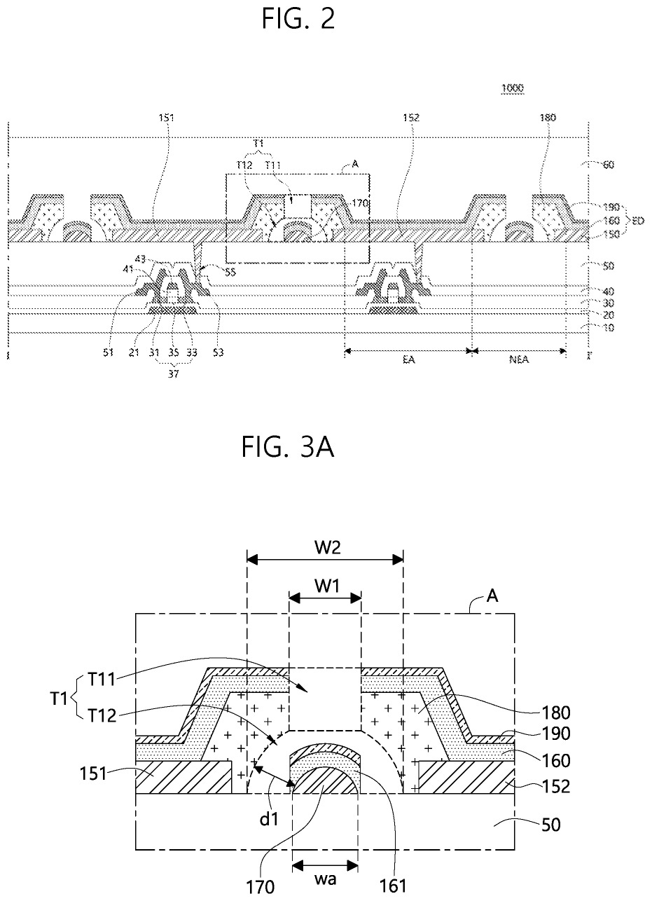

Referring to FIG. 1A, the light emitting display device includes a plurality of emission areas EA disposed on a planarization layer 50 and spaced apart from one another, and a reflective metal 170 disposed among the spaced emission areas EA. The emission areas EA are areas in which a plurality of anodes (150 in FIG. 2) is exposed by a bank (180 in FIG. 1B). The reflective metal 170 can be provided in plural such that the plural reflective metals 170 are spaced apart from one another among the emission areas EA. Accordingly, the reflective metal 170 can be exposed in one cross-section taken between two emission areas EA adjacent to each other, but may not be exposed in another cross-section.

In addition, although the reflective metal 170 is shown as having a circular shape in plan view in the first embodiment, the present disclosure is not limited thereto, and the reflective metal 170 can have various shapes such as a triangular shape, a quadrangular shape, a polygonal shape, etc.

In some cases, the reflective metal 170 may not be provided between certain emission areas EA.

FIG. 1B is an enlarged plan view of an area C1 in FIG. 1A.

Referring to FIG. 1B, the bank 180 is configured to expose respective emission areas EA of a plurality of anodes 150 including a first anode (151 in FIG. 2) and a second anode (152 in FIG. 2). The reflective metal 170, which is provided in a non-emission area NEA, is exposed through a first trench T11 of the bank 180. In addition to the first trench T11, the bank 180 also includes a second trench T12 overlapping with the first trench T11 while having an area greater than that of the first trench T11. The first trench T11 can take the form of a single trench extending continuously along a plurality of reflective metals 170. The first trench T11 of the bank 180 is formed along respective edges of a plurality of emission areas EA. However, the first trench T11 of the bank 180 is not formed at least a portion of the edges of each of the plurality of emission areas EA in order to enable a cathode 190 formed on the entire surface of a substrate to apply a voltage to the plurality of emission areas EA. In addition, the second trench T12 of the bank 180 overlaps with the first trench T11, and is provided along a periphery of the first trench T11.

FIG. 2 is a cross-sectional view taken along line I-I′ in FIG. 1A, showing the light emitting display device according to the embodiment of the present disclosure.

As shown in FIG. 2, the light emitting display device according to the embodiment of the present disclosure, which is designated by reference numeral 1000, includes a substrate 10, a thin film transistor TFT, a light shielding layer 21, a buffer layer 20, an interlayer insulating layer 30, a protective layer 40, a planarization layer 50, a light emitting element ED, the bank 180, and an encapsulation layer 60.

The substrate 10 is divided into an active area in which a screen is displayed, and a non-active area in which no screen is displayed. The active area includes a plurality of emission areas EA and a non-emission area NEA disposed in an area other than the emission areas EA. Here, the substrate 10 can be formed of glass or a plastic substrate having flexibility. For example, in the case of the plastic substrate, the plastic substrate can include polyimide or polyamide. In addition, a circuit device including various signal lines for a data signal and a gate signal, transistors such as a switching thin film transistor and a driving thin film transistor, a capacitor, etc. is formed on the substrate 10 in each emission area EA. In the embodiment of the present disclosure, for convenience of description, only one thin film transistor TFT, which drives one emission area EA, is shown.

The thin film transistor TFT includes an active layer 37, a gate electrode 43 overlapping with a channel region 35 of the active layer 37 under the condition that a gate insulating layer 41 is interposed therebetween, and a source electrode 51 and a drain electrode 53 connected to opposite sides of the active layer 37, respectively.

The active layer 37 of the thin film transistor TFT includes a source region 31 and a drain region 33 at opposite sides of the channel region 35 under the condition that the channel region 35 is interposed therebetween. Each of the source region 31 and the drain region 33 is formed of a semiconductor material doped with an n-type or p-type impurity. The channel region 35 can be formed of a semiconductor material not doped with an n-type or p-type impurity.

The gate electrode 43 of the thin film transistor TFT is provided to overlap with the channel region 35 of the active layer 37 while having the same width under the condition that the gate insulating layer 41 is interposed therebetween. The gate insulating layer 41 has the same pattern as that of the gate electrode 43, and overlaps with the channel region 35 of the active layer 37. For example, the gate electrode 43 can be a single layer or multiple layers made of one of molybdenum (Mo), aluminum (Al), chromium (Cr), gold (Au), titanium (Ti), nickel (Ni), neodymium (Nd), and copper (Cu), or an alloy thereof. Meanwhile, the gate insulating layer 41 can be made of an inorganic insulating material. For example, the gate insulating layer 41 can be constituted by a silicon oxide (SiOₓ) layer, a silicon nitride (SiNₓ) layer, a silicon oxynitride (SiOₓN_{y}) layer, or multiple layers thereof.

The light shielding layer 21 on the substrate 10 is disposed under the active layer 37 while overlapping with at least the channel region 35 of the active layer 37 of the thin film transistor TFT. The light shielding layer 21 prevents external light from being transmitted to the thin film transistor TFT after passing through the substrate 10. For example, the light shielding layer 21 can be constituted by a single layer of one of metal materials such as molybdenum (Mo), titanium (Ti), aluminum-neodymium (AlNd), aluminum (Al), chromium (Cr), or an alloy thereof, or can be constituted by a multilayer structure using the metal materials.

The buffer layer 20 on the light shielding layer 21 is provided to cover the light shielding layer 21. For example, the buffer layer 20 can be constituted by a single-layer structure or a multilayer structure made of silicon oxide (SiOₓ) or silicon nitride (SiNₓ).

The interlayer insulating layer 30 on the buffer layer 20 can include a source contact hole and a drain contact hole respectively exposing the source region 31 and the drain region 33 of the active layer 37, and can be provided to cover the gate insulating layer 41 and the gate electrode 43. For example, the interlayer insulating layer 30 can be made of an inorganic insulating material. For example, the interlayer insulating layer 30 can be constituted by a silicon oxide (SiOₓ) layer, a silicon nitride (SiNₓ) layer, a silicon oxynitride (SiOₓN_{y}) layer, or multiple layers thereof.

The source electrode 51 and the drain electrode 53 can be provided on the interlayer insulating layer 30, to form the same layer. The source electrode 51 and the drain electrode 53 are connected to the source region 31 and the drain region 33 of the active layer 37 via the source contact hole and the drain contact hole, respectively. For example, when the source electrode 51 and the drain electrode 53 form a single layer, the source electrode 51 and the drain electrode 53 can be made of one selected from the group consisting of molybdenum (Mo), aluminum (Al), chromium (Cr), gold (Au), titanium (Ti), nickel (Ni), neodymium (Nd), and copper (Cu), or an alloy thereof.

The protective layer 40 on the interlayer insulating layer 30 can be provided to cover the thin film transistor TFT. Accordingly, the thin film transistor TFT can be protected by the protective layer 40. For example, the protective layer 40 is a kind of inorganic insulating layer, and can be constituted by a single layer or multiple layers of a silicon oxide (SiOₓ) layer, a silicon nitride (SiNₓ) layer, or a silicon oxynitride (SiOₓN_{y}) layer.

The planarization layer 50 can be provided on the protective layer 40, for surface planarization. In some cases, the protective layer 40 can be omitted when the planarization layer 50 also functions to protect the thin film transistor TFT. For example, the planarization layer 50 is a kind of organic insulating layer, and can be made of one of photoacryl, polyimide, benzocyclobutene series resin, and acrylate, etc. If necessary, the planarization layer 50 can be formed of multiple layers. The planarization layer 50 can also be referred to as an “overcoat layer”.

The light emitting element ED, which includes one of the plurality of anodes 150 including the first and second anodes 151 and 152, an organic layer 160, and the cathode 190, is provided on the planarization layer 50. The plurality of anode 150 of the light emitting element ED is respectively connected to the drain electrode 53 of the thin film transistor TFT via a contact hole 55. When the anode 150 receives current from the thin film transistor TFT in the light emitting element ED as described above, an electric field is formed between the anode 150 and the cathode 190 and, as such, the organic layer 160 emits light.

In addition, the light emitting display device 1000 according to the embodiment of the present disclosure includes a first anode 151 and a second anode 152 provided to be spaced apart from each other, a reflective metal 170 provided between the first anode 151 and the second anode 152, and a bank 180 disposed on the reflective metal 170 in a non-emission area NEA, to expose an emission area EA of each of the first anode 151 and the second anode 152, while including a trench T1 having a width gradually increasing as the trench T1 extends downwards toward the reflective metal 170.

The reflective metal 170 is provided between the first anode 151 and the second anode 152. In addition, the reflective metal 170 is disposed on the same layer as the first anode 151 and the second anode 152. Here, disposition of the reflective metal 170 on the same layer as the first anode 151 and the second anode 152 only means that the reflective metal 170 is disposed on the planarization layer 50 on which the first anode 151 and the second anode 152 are disposed, and does not mean that the reflective metal 170, the first anode 151, and the second anode 152 are formed in the same process or formed of the same material.

If necessary, the reflective metal 170 can be formed simultaneously with the first anode 151 and the second anode 152 in the same process, using the same material. When the reflective metal 170 is formed using the same material as that of the first anode 151 and the second anode 152, a separate procedure and a separate mask for formation of the reflective metal 170 are unnecessary and, as such, the process can be simplified.

In another case, when the first anode 151 and the second anode 152 are constituted by plural layers, the reflective metal 170 can be formed of a part of the plural layers of the first anode 151 and the second anode 152.

In another case, the reflective metal 170 can be formed on the same layer as the first anode 151 and the second anode 152, but can be formed of a material different from that of the first anode 151 and the second anode 152.

When the reflective metal 170 is formed simultaneously with the first anode 151 and the second anode 152 in the same process, using the same material, each of the reflective metal 170, the first anode 151, and the second anode 152 can be formed to have a multilayer structure including a transparent conductive layer and an opaque conductive layer having a high reflection efficiency. The transparent conductive layer is formed of a material having a relativity high work function such as indium tin oxide (ITO) or indium zinc oxide (IZO), and the opaque conductive layer can be constituted by a single layer or multiple layers of one selected from the group consisting of silver (Ag), aluminum (Al), copper (Cu), molybdenum (Mo), titanium (Ti), nickel (Ni), chromium (Cr), and tungsten (W), or an alloy thereof. For example, the reflective metal 170 can be formed by a structure in which a transparent conductive layer, an opaque conductive layer, and a transparent conductive layer are sequentially stacked, or can be formed by a structure in which a transparent conductive layer and an opaque conductive layer are sequentially stacked.

In another case, when each of the reflective metal 170, the first anode 151, and the second anode 152 is constituted by a multilayer structure, the reflective metal 170 can be formed by a part of layers in the multilayer structures of the first anode 151 and the second anode 152, or the first anode 151 and the second anode 152 can be formed by a part of layers in the multilayer structure of the reflective metal 170.

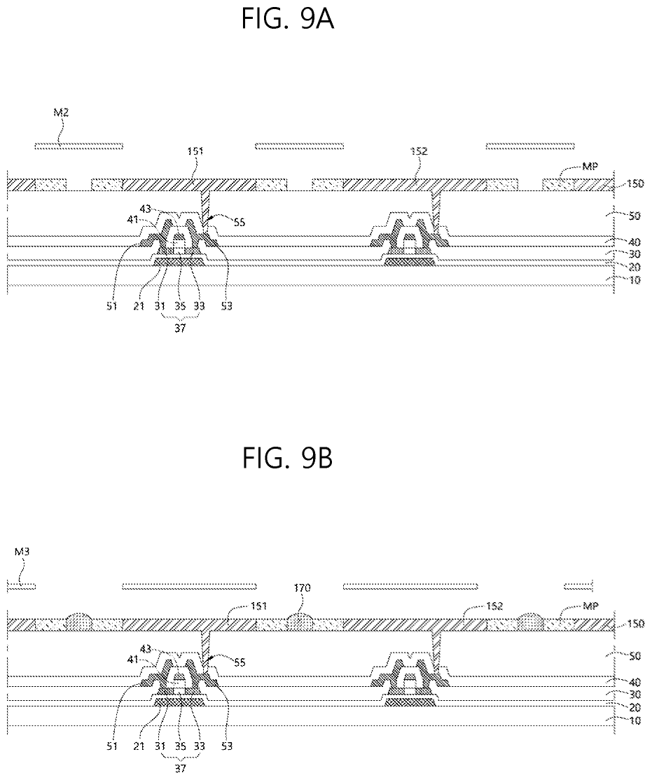

In another case, the reflective metal 170 can be made of a material different from that of the first anode 151 and the second anode 152, in order to increase reflectivity thereof. In this case, the reflective metal 170, the first anode 151, and the second anode 152 can be formed using different masks, and manufacturing methods thereof will be described later with reference to FIGS. 9A and 9B.

For example, the reflective metal 170 can include at least one of aluminum (Al), silver (Ag), or titanium (Ti). The reflective metal 170 is made of a metal having reflectivity capable of generating diffuse reflection of a laser beam irradiating the reflective metal 170, thereby etching an inner portion of the bank 180. Accordingly, the reflective metal 170 can induce the trench T1 in the bank 180 to be formed along a shape of the reflective metal 170.

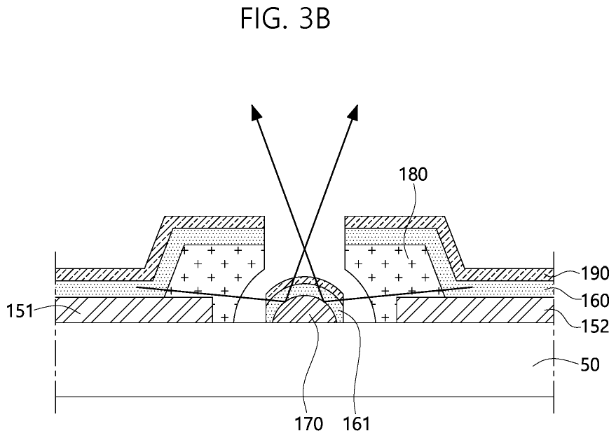

In addition, the reflective metal 170 can reflect light advancing to the inside of the bank 180 after being emitted from the organic layer 160, along a path indicated by an arrow in FIG. 3B. In other words, the reflective metal 170 according to the embodiment of the present disclosure again reflects, to the emission area EA, light advancing to the bank 180 of the non-emission area NEA without being upwardly emitted through the emission area EA of each of the first anode 151 and the second anode 152. Thus, the embodiment of the present disclosure has effects of achieving an increase in luminous efficacy and an enhancement in viewing angle by virtue of the reflective metal 170.

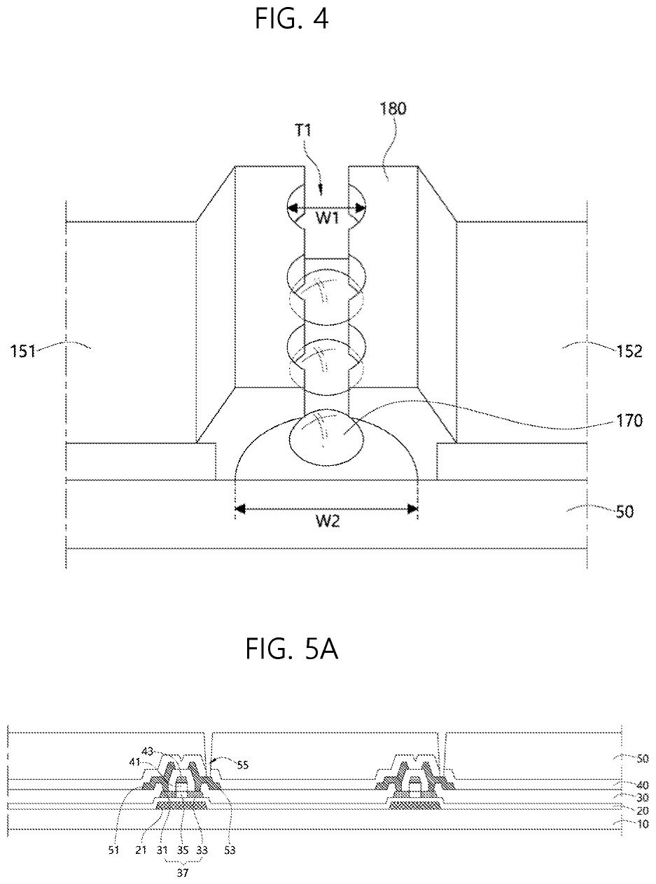

Referring to FIG. 4, which is a perspective view corresponding to FIGS. 3A and 3B, the reflective metal 170 according to the first embodiment of the present disclosure can be provided in plural such that the plural reflective metals 170 are spaced apart from one another between the first anode 151 and the second anode 152. Of course, the present disclosure is not limited to the above-described condition, and 4 or more reflective metals 170 can be disposed, or three reflective metals 170 can be disposed in parallel to be spaced apart from one another in one direction and a plurality of reflective metals 170 can be arranged in another direction, if necessary.

Referring to a cross-sectional view of FIG. 3A and the perspective view of FIG. 4 enlarging an area A of FIG. 2, the reflective metal 170 has an area gradually increasing as the reflective metal 170 extends downwards. Herein, the reflective metal 170 has a maximum width wa at a lower surface thereof. The maximum width wa of the reflective metal 170 is 1/40 to 1/20 times a width of each of the first anode 151 and the second anode 152. Accordingly, an upper surface of the reflective metal 170 can have a curved or round shape when viewed in cross-section, as compared to flat upper surfaces of the first anode 151 and the second anode 152. In accordance with the first embodiment of the present disclosure, the reflective metal 170 can have a hemispherical shape. In accordance with the shape of the reflective metal 170 as described above, the trench T1 of the bank 180 can include a first trench T11 and a second trench T12 having different shapes.

The bank 180 is disposed above the reflective metal 170 in the non-emission area NEA, to expose the emission area EA of each of the first anode 151 and the second anode 152, while including the trench T1 having a width gradually increasing as the trench T1 extends downwards toward the reflective metal 170. For example, the bank 180 can be made of an organic material such as polyimide, acrylate, benzocyclobutene series resin, etc.

The bank 180 overlaps with an edge of each of the first anode 151 and the second anode 152 and, as such, exposes the emission area EA of each of the first anode 151 and the second anode 152. In addition, the bank 180 includes the trench T1 between the first anode 151 and the second anode 152. In detail, the trench T1 of the bank 180 includes the first trench T11, which exposes the reflective metal 170 while overlapping with the reflective metal 170, and the second trench T12, which is disposed under the first trench T11, and spaces an inner surface of the bank 180 from an upper surface of the reflective metal 170 by a first distance d1. For example, the second trench T12 defines or provides a space extending from the inner surface of the bank 180 to the upper surface of the reflective metal 170 by the first distance d1.

As described above, the bank 180 includes the trench T11 exposing the reflective metal 170 while overlapping with the reflective metal 170. The first trench T11 has a width W1 corresponding to the maximum width wa of the reflective metal 170. Accordingly, the first trench T11 can expose the reflective metal 170 from the bank 180. In addition, in accordance with the embodiment of the present disclosure, a laser beam irradiates the entirety of the upper surface of the reflective metal 170 in a laser process for inducing diffuse reflection of the laser beam toward the reflective metal 170. Of course, the present disclosure is not limited to the above-described condition, and the width W1 of the first trench T11 can be smaller than the maximum width wa of the reflective metal 170 when it is unnecessary to completely expose the reflective metal 170 from the bank 180 in some cases. If necessary, the width W1 of the first trench T11 can be greater than the maximum width wa of the reflective metal 170.

In addition, the bank 180 includes the second trench T12 disposed under the first trench T11, and configured to space the inner surface of the bank 180 apart from the upper surface of the reflective metal 170 by the first distance d1. The second trench T12 described above has an undercut shape under the first trench T11. Accordingly, even when the organic layer 160 and the cathode 190 deposited over the bank 180 in accordance with the embodiment of the present disclosure are partially formed at a side portion of the first trench T11, the organic layer 160 and the cathode 190 can be disconnected at the second trench T12. Thus, in accordance with the embodiment of the present disclosure, the first and second trenches T11 and T12 having different shapes are provided at the bank 180 and, as such, a portion of the organic layer 160 between the first anode 151 and the second anode 152 can be completely disconnected.

In this case, the inner surface of the bank 180 can have an arch shape when viewed in cross-section. The arch-shaped inner surface of the bank 180 efficiently disperses a load transferred from a plurality of layers deposited over the bank 180, which includes the organic layer 160 and the cathode 190, thereby providing an effect of stably supporting the resultant structure. When the inner surface of the bank 180 is formed to have a width gradually increasing while extending downwards such that the inner surface of the bank 180 has a shape similar to an arch shape, even though the inner surface of the bank 180 does not have a perfect arch shape, the inner surface of the bank 180 can have an effect of efficiently dispersing the above-described load transferred from an upper side. Thus, the inner surface of the bank 180 according to the embodiment of the present disclosure can have a remarkable effect of stably supporting the structure, as compared to a structure having a trench having a rectangular undercut shape or a non-arch shape when viewed in cross-section.

The organic layer 160 is provided on the first anode 151, the second anode 152, and the bank 180. In addition, an organic dummy pattern 161 separated from the organic layer 160 is provided on the reflective metal 170 in the trench T1. In this case, the organic layer 160 can include at least an emission layer EML. The emission layer EML can be selectively formed, corresponding to an emission area in the active area. Common layers associated with a hole transport layer HTL and a hole injection layer HIL and common layers associated with an electron transport layer ETL and an electron injection layer EIL can be further provided under and over the emission layer EML, respectively. For example, the organic layer 160 can mean a single stack constituted by multiple layers including a hole injection layer HIL, a hole transport layer HTL, an emission layer EML, an electron transport layer ETL, and an electron injection layer EIL. Alternatively, the organic layer 160 can mean a tandem structure including a plurality of stacks including a first stack and a second stack, and a charge generation layer CGL disposed among the stacks. Here, the charge generation layer CGL can be constituted by a double layer of an n-type layer and a p-type layer. In addition, the tandem structure can be multiple stacks including three stacks or more. Each of the stacks can include a hole transport layer HTL, an emission layer EML, and an electron transport layer ETL. The hole injection layer HIL, the hole transport layer HTL, the electron injection layer EIL, and the electron transport layer ETL can be common layers formed at a plurality of sub-pixels in common. The emission layer EML in the stack of the organic layer 160 having the tandem structure can also be a common layer formed at a plurality of sub-pixels in common.

The organic layer 160 can be formed of a material deposited through vaporization, and can be deposited on a flat portion of the upper surface of the bank 180 such that the organic layer 160 has a uniform surface, but can have difficulty being deposited on a vertical side surface of the bank 180. In the embodiment of the present disclosure, accordingly, the organic layer 160 can be disconnected at the trench T1 of the bank 180, as shown in FIG. 3A, and, as such, disconnected portions of the organic layer 160 can be disposed on the bank 180 and the reflective metal 170, respectively. For example, in the embodiment of the present disclosure, the organic layer 160 is separated into a portion of the organic layer 160, which is disposed on the first anode 151, the second anode 152 and the bank 180, and an organic dummy pattern 161 disposed on the reflective metal 170 in the trench T1. Accordingly, in the embodiment of the present disclosure, separation and spacing of the organic layer can be effectively achieved at the trench T1 of the bank 180 formed to have an arch shape.

The cathode 190 is provided on the portion of the organic layer 160 and the organic layer dummy pattern 161. Similarly to the organic layer 160, the cathode 190 can be disconnected at the trench T1 and, as such, disconnected portions of the cathode 190 can be disposed over the bank 180 and the reflective metal 170, respectively. Of course, the cathode 190 is formed of a metal material having better step coverage characteristics than those of the organic layer 160 and, as such, can be disposed at a portion of the side surface of the bank 180 where the bank 180 contacts the first trench T11. Even when the cathode 190 is formed at the side surface portion of the bank 180 where the bank 180 contacts the first trench T11, the cathode 190 can be disconnected at the trench T1 of the bank 180 by virtue of the second trench T12 configured to have a gradually-increasing width greater than the width of the first trench T1. In the embodiment of the present disclosure, the cathode 190 is shown as not being disposed at the vertical side surface portion of the bank 180. For example, the cathode 190 can be made of a transparent conductive material such as indium tin oxide (ITO) or indium zinc oxide (IZO), or can be made of silver (Ag), aluminum (Al), magnesium (Mg), calcium (Ca), or an alloy thereof while having a small thickness enabling passage of light therethrough.

The encapsulation layer 60 is provided on the cathode 190, to cover the entirety of the active area and the entirety of the non-active area. The encapsulation layer 60 prevents penetration of oxygen and moisture into the light emitting element ED, thereby increasing the lifespan of the light emitting display device. The encapsulation layer 60 can be formed to have, for example, a structure in which one or more pairs of an inorganic encapsulation layer and an organic encapsulation layer are stacked or a structure in which a filler and a counterpart substrate are stacked.

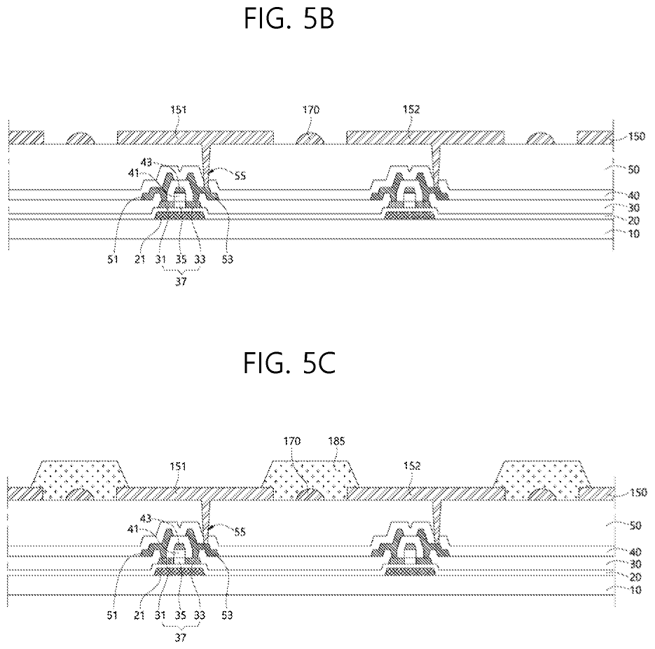

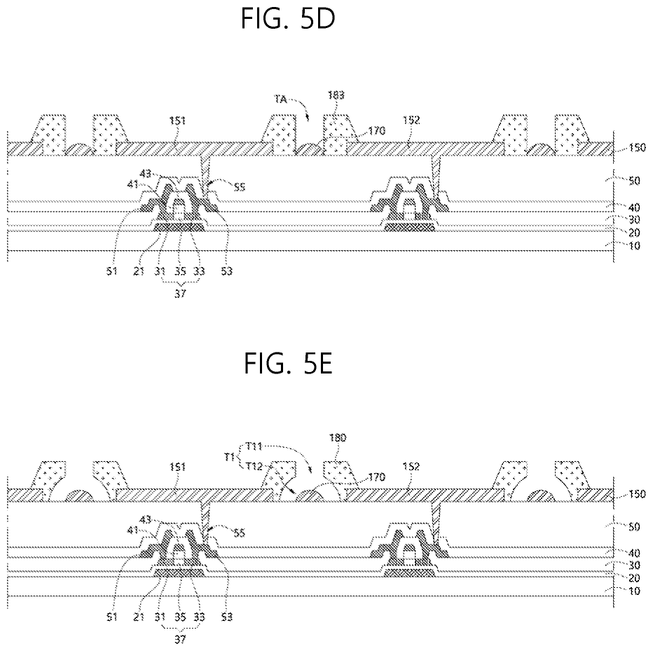

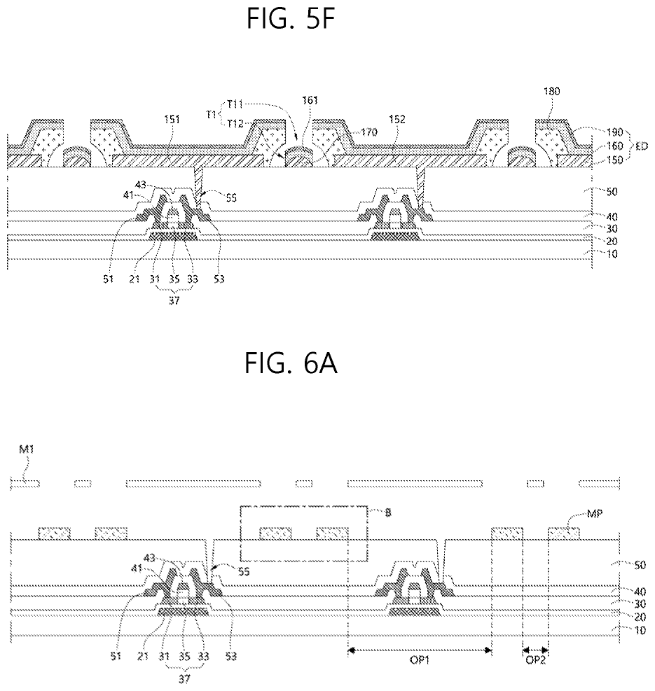

Hereinafter, a method of manufacturing a light emitting display device in accordance with an embodiment of the present disclosure will be described with reference to cross-sectional views of FIGS. 5A to 5F.

Referring to FIG. 5A, a light shielding layer 21, a buffer layer 20, and a thin film transistor TFT are sequentially formed on a substrate 10. In detail, the buffer layer 20 is formed on the substrate 10 formed with the light shielding layer 21, and an active layer 37 is formed on the buffer layer 20 through a mask process. Subsequently, a gate insulating layer 41 is formed on the buffer layer 20 formed with the active layer 37, and a gate electrode 43 is formed on the gate insulating layer 41. The gate insulating layer 41 and the gate electrode 43 are simultaneously formed through a mask process. Thereafter, an interlayer insulating layer 30 including source and drain contact holes is formed on the gate electrode 43 through a mask process. Next, source and drain electrodes 51 and 53 are formed on the substrate 10 formed with the interlayer insulating layer 30 through a mask process. A protective layer 40 and a planarization layer 50, which include an anode contact hole, are then sequentially stacked on the interlayer insulating layer 30 formed with the source and drain electrodes 51 and 53.

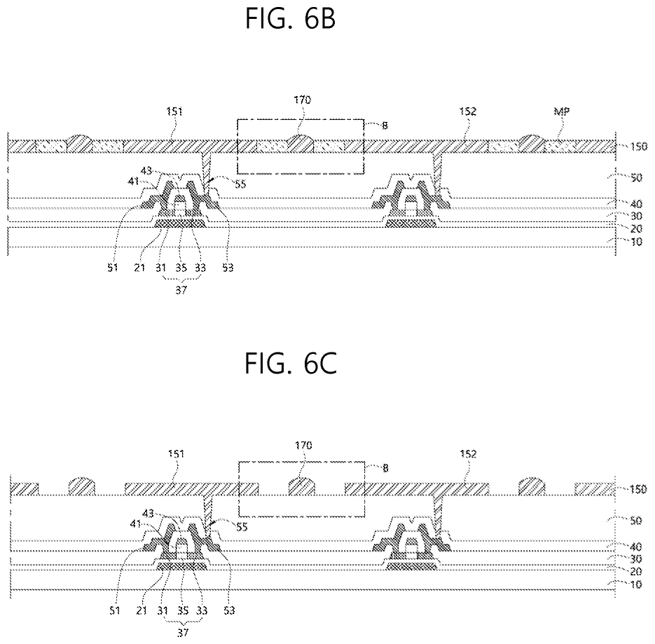

Thereafter, referring to FIG. 5B, a plurality of anodes 150 spaced apart from one another while including a first anode 151 and a second anode 152 is formed on the planarization layer 50, and reflective metals 170 are formed among the spaced anodes 150, respectively. In this case, each anode 150 and each reflective metal 170 can be formed of the same material. In some cases, the anode 150 and the reflective metal 170 can be formed of different materials. When the anode 150 and the reflective metal 170 are formed of the same material, the anode 150 and the reflective metal 170 can be formed using one mask. The above-described cases will be described later in detail with reference to FIGS. 6A to 6C and FIGS. 9A and 9B.

In addition, the reflective metal 170 is formed to have a size corresponding to 1/40 to 1/20 times a size of the anode 150. Since a trench T1 is formed using the reflective metal 170, which has a small size, in accordance with the embodiment of the present disclosure, it can be possible to form a trench T1 having a remarkably small size, as compared to the case in which a trench is formed using a mask.

Next, referring to FIG. 5C, first bank patterns 185 are formed on the planarization layer 50 formed with the anodes 150 and the reflective metals 170 through a mask process. In this case, the first bank patterns 185 expose respective emission areas EA of the plurality of anodes 150 through a mask process. In addition, the first bank patterns 185 are formed to completely cover an area except for the emission areas EA and, as such, cover upper surfaces of the reflective metals 170 in a non-emission area NEA.

Subsequently, referring to FIG. 5D, an upper trench TA is formed through removal of an upper portion of each first bank pattern 185, thereby forming a second bank pattern 183. Here, the maximum width of the upper trench TA can be formed corresponding to a maximum width wa of the reflective metal 170. Accordingly, the second bank pattern 183 exposes the reflective metal 170 through the upper trench TA. However, the upper trench TA of the present disclosure is not limited to the above-described structure, and the width of the upper trench TA can be formed to be bigger than or smaller than the maximum width wa of the reflective metal 170, if necessary.

Next, referring to FIG. 5E, a second trench T12 having an arch shape is formed at the second bank pattern 183 under the upper trench TA. As the second trench T12 is defined, the upper trench TA disposed over the second trench T12 while contacting the second trench T12 forms a first trench T11. Accordingly, a bank 180, which includes the first trench T11 exposing the reflective metal 170 while overlapping with the reflective metal 170, and the second trench T12 disposed under the first trench T11 while spacing (e.g., providing a space extending to) an inner surface of the bank 180 from an upper surface of the reflective metal 170 by a first distance d1, is formed.

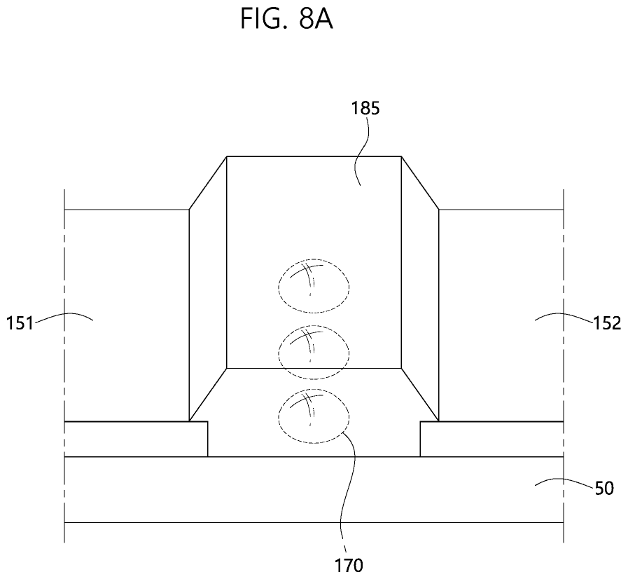

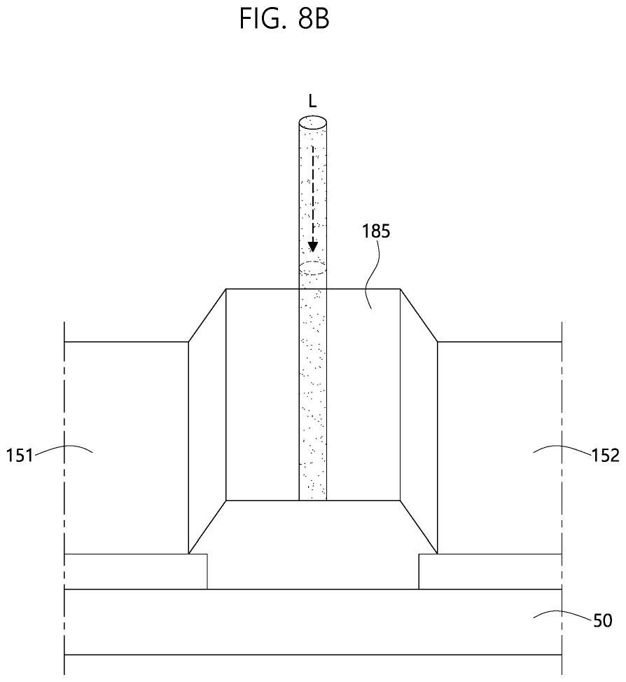

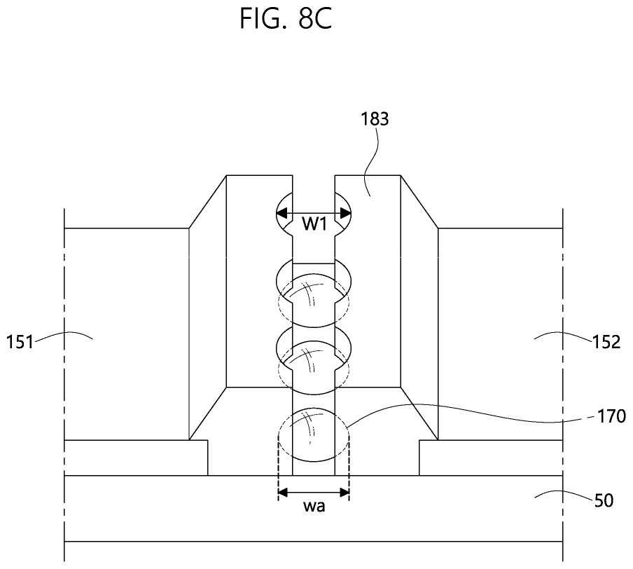

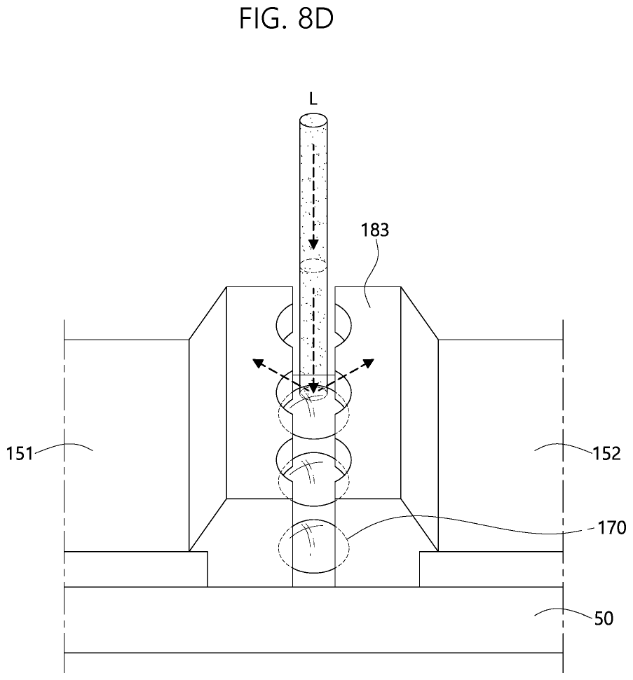

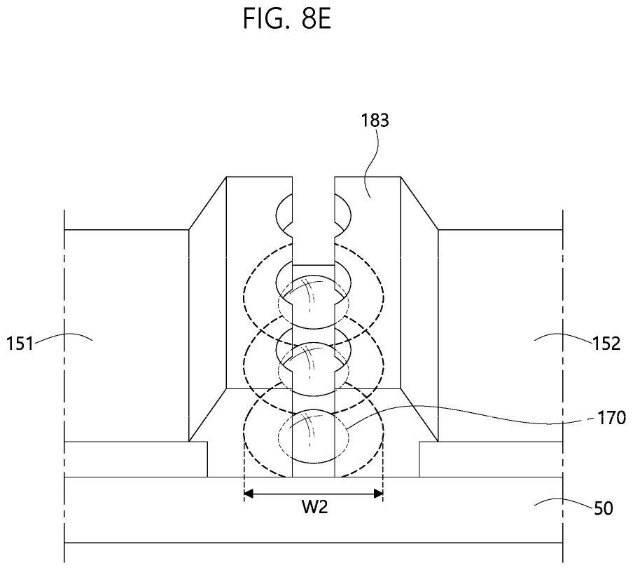

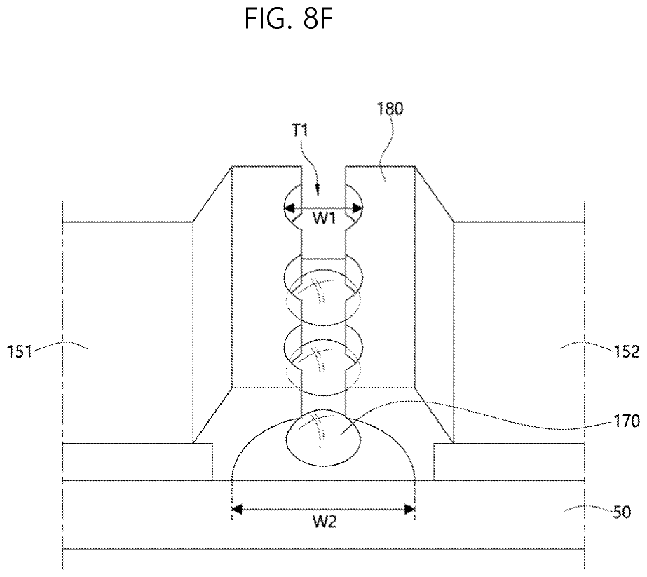

Methods of manufacturing the upper trench TA and the second trench T12 in FIGS. 5D and 5E are performed using a laser. This will be described later with reference to FIGS. 8A to 8F.

Thereafter, referring to FIG. 5F, an organic layer 160 and a cathode 190 are deposited on the entire upper surfaces of the bank 180 formed with the trench T1 and the anodes 150. Here, the organic layer 160 is separated at the trench T1 of the bank 180 and, as such, forms an organic dummy pattern 161 on the reflective metal 170. Similarly, the cathode 190 is separated at the trench T1 of the bank 180 and, as such, portions thereof are formed on the reflective metal 170 and the organic dummy pattern 161, respectively. Thus, in the embodiment of the present disclosure, the organic layer 160 is separated into portions of the organic layer 160 and organic layer dummy patterns 161 among a plurality of anodes 150 and, as such, there is an effect of preventing leakage current from flowing among the anodes 150.

In addition, in the embodiment of the present disclosure, the reflective metal 170 is provided in the non-emission area NEA between the emission areas EA and, as such, a separate space for formation of the reflective metal 170 is not formed. In addition, since the reflective metal 170 is formed to have a size corresponding to 1/40 to 1/20 times a size of the anode 150 in the embodiment of the present disclosure, the trench T1 can be formed to have a small size. In the embodiment of the present disclosure, accordingly, it can be possible to separate the organic layer 160 through formation of the trench T1 having a small size and, as such, an area of the trench T1 occupying the non-emission area NEA is reduced. Thus, an effect of achieving high resolution is provided.

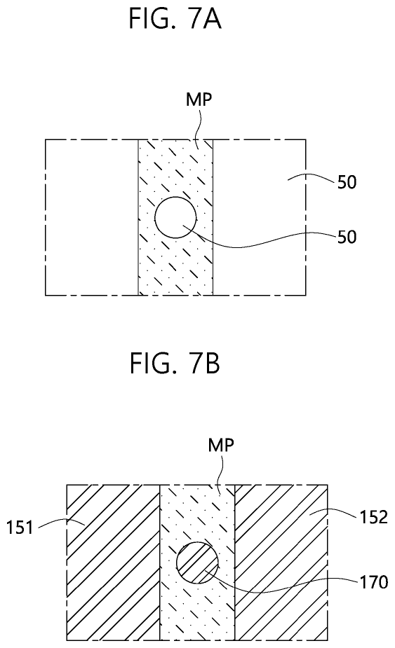

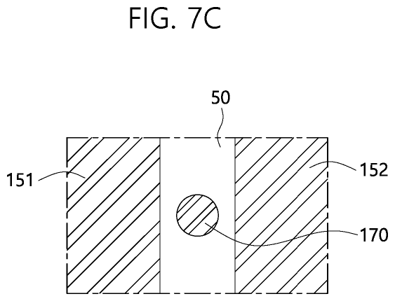

FIGS. 6A to 6C and FIGS. 7A to 7C are respectively cross-sectional views and plan views concretely showing the light emitting display device manufacturing method shown in FIG. 5B. FIGS. 6A to 6C and FIGS. 7A to 7C are associated with mask processes for formation of the anode 150 and the reflective metal 170.

Referring to FIG. 6A, a pattern definition part MP, which has a first opening OP1 and a second opening OP2 having a smaller size than that of the first opening OP1, is formed using a first mask M1. Here, the second opening OP2 is formed to have a width corresponding to 1/40 to 1/20 times a width of the first opening OP1.

Referring to FIG. 7A, enlarging an area B in FIG. 6A, the pattern definition part MP is formed on the planarization layer 50 while having the second opening OP2 which has a circular shape. For example, the material of the pattern definition part MP can be an organic material including fluorinated chains. The pattern definition part MP as described above has low surface energy due to characteristics of the organic material and, as such, can have a property causing a metal material contacting an upper surface of the pattern definition part MP to flow outside the pattern definition part MP.

Next, referring to FIGS. 6B and 7B, a first metal material is deposited on the planarization layer 50 formed with the pattern definition part MP. The first metal material flows into the first opening OP1 and the second opening OP2 over the pattern definition part MP. In this case, the first metal material is deposited in a flat state in the first opening OP1, but is concentrated in the form of a hemisphere in the second opening OP2 which has a relatively small area. Accordingly, a flat anode 150 is formed at the first opening OP1, and a hemispherical reflective metal 170 is formed at the second opening OP2. The reflective metal 170 is shown in the manufacturing process view as having a structure in which a side surface thereof contacting the pattern definition part MP is vertical, and an upper surface thereof formed at an upper side than the pattern definition portion MP has a hemispherical shape, in accordance with the pattern definition part MP. However, the present disclosure is not limited to the above-described structure, and a reflective metal 170 having a perfect hemispherical shape as shown in FIG. 2 can be formed in accordance with the thickness of the pattern definition part MP or the degree of deposition of the first metal material constituting the reflective metal 170.

Next, referring to FIGS. 6C and 7C, the pattern definition part MP is stripped and, as such, the anode 150 and the reflective metal 170 formed on the planarization layer 50 remain. Thus, in the embodiment of the present disclosure, both the anode 150 and the reflective metal 170 are formed through one mask process using the first mask M1. Of course, when the anode 150 and the reflective metal 170 are formed of different materials, respectively, one or more processes can be added to or omitted from the processes of FIGS. 6A to 6C.

FIGS. 8A to 8F are perspective views concretely showing a method of manufacturing the trench T1 of the bank 180 shown in FIGS. 5C to SE.

Referring to FIG. 8A, three reflective metals 170 are disposed in the form of islands between the first anode 151 and the second anode 152. Three or fewer reflective metals 170 can be disposed, or four or more reflective metals 170 can be disposed, but embodiments of the present disclosure are not limited thereto. In addition, a first bank pattern 185 is disposed on the first anode 151, the second anode 152, and the reflective metals 170. The first bank pattern 185 is disposed to overlap with edges of the first anode 151 and the second anode 152, in order to expose emission areas of the first anode 151 and the second anode 152.

Referring to FIG. 8B, laser drilling using a laser beam L is performed on the first bank pattern 185. The laser drilling is performed such that the laser beam L is directed downwards toward the reflective metals 170. It can be possible to remove the first bank pattern 185 disposed over the reflective metals 170, using a method of applying an external physical force, in place of the laser drilling using the laser beam L. Accordingly, the present disclosure is not limited to the above-described conditions.

Referring to FIG. 8C, as the laser drilling is completed, a second bank pattern 183 including an upper trench TA is formed such that the upper trench TA has a width w1 corresponding to a maximum width wa of each reflective metal 170. The upper trench TA is formed to have a structure extending continuously along the three reflective metals 170. Accordingly, the upper trench TA has a round shape on the reflective metals 170 while having a line shape among the reflective metals 170.

Referring to FIG. 8D, the laser beam L irradiates each reflective metal 170 through the first trench T1 under the condition that power of the laser beam Lis varied. As the irradiated laser beam L is incident upon an upper surface of the reflective metal 170, diffuse reflection thereof is generated. The laser beam L is irradiated along a hemispherical shape of the upper surface of the reflective metal 170.

Referring to FIG. 8E, diffuse reflection of the laser beam L can be generated in a range corresponding to a second width W2 around the reflective metal 170 through a variation in power of the laser beam L. As a result, a second trench T12 having a greater area than that of the first trench T11 can be formed in accordance with the embodiment of the present disclosure. The second width W2 of the second trench T12 can be adjusted through a variation in power of the laser beam L, or can be adjusted through a variation in reflectivity according to the material of the reflective metal 170.

Thereafter, referring to FIG. 8F, the bank 180 is formed to include the first trench T11 exposing the reflective metal 170 while overlapping with the reflective metal 170, and the second trench T12 disposed under the first trench T11 while spacing the inner surface of the bank 180 from the upper surface of the reflective metal 170 by a first distance d1. The second trench T12 has a shape in which the width of the second trench T12 increases gradually from a first width w1 of the first trench T11, and is formed along a hemispherical shape of the reflective metal 170 such that the cross-section of the second trench T12 has an arch shape. In the embodiment of the present disclosure, accordingly, it can be possible to disconnect the organic layer 160 and the cathode 190 deposited on the bank 180 through provision of the first trench T11 and the second trench T12 at the bank 180. In the embodiment of the present disclosure, accordingly, there is an effect of preventing leakage current from flowing between the sub-pixels.

FIGS. 9A and 9B are cross-sectional views showing a method of forming the anode 150 and the reflective metal 170 after the formation process shown in FIG. 6A in accordance with another embodiment of the present disclosure. The embodiment of FIGS. 9A and 9B relates to a manufacturing method in the case in which the anode 150 and the reflective metal 170 are formed of different materials, respectively. In accordance with this embodiment, the anode 150 and the reflective metal 170 are formed through different mask processes, respectively.

In detail, referring to FIG. 9A, a pattern definition part MP, which includes a plurality of first openings OP1, and a second opening OP2 disposed among the first openings OP1 while having a size corresponding to 1/40 to 1/20 times a size of each first opening OP1, is provided on the planarization layer 50, using a first mask M1. A second metal material is then deposited using a second mask M2, thereby forming the anode 150 at each of the first opening OP1.

Subsequently, referring to FIG. 9B, a third metal material different from the second metal material is deposited on the pattern definition part MP, using a third mask M3, thereby forming the reflective metal 170 at the second opening OP2. In this case, the third mask M3 is configured to expose the pattern definition part MP and, as such, the third metal material is also deposited on the pattern definition part MP. Accordingly, the reflective metal 170, which has a hemispherical shape, is formed at the second opening OP2 of the pattern definition part MP.

Thus, in the case of FIGS. 9A and 9B, the anode 150 and the reflective metal 170 can be formed of different materials, using the two masks M2 and M3, respectively.

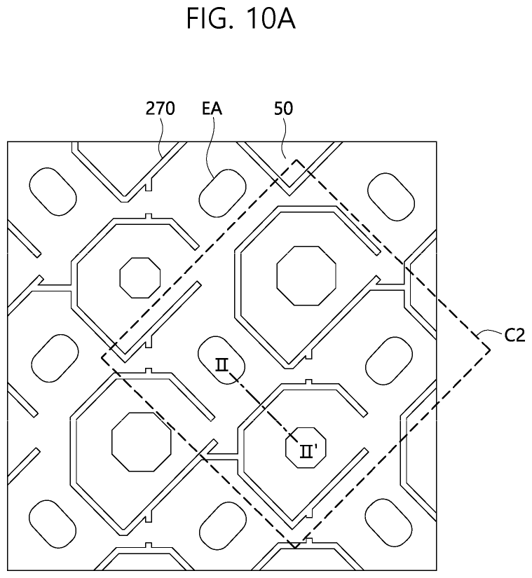

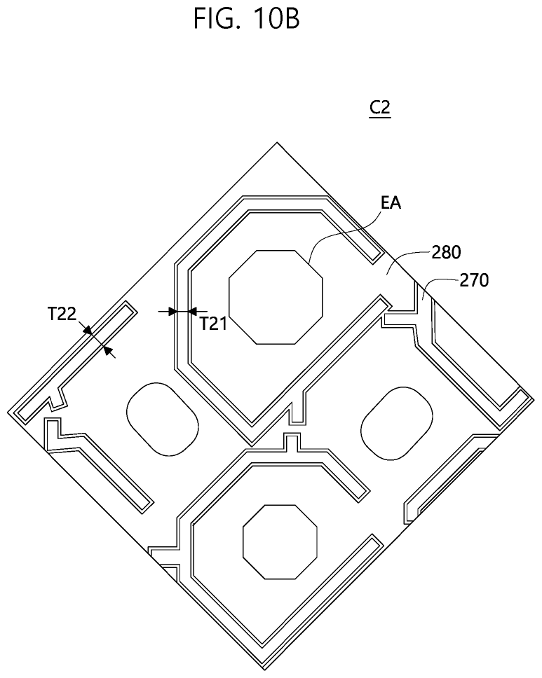

FIG. 10A is a plan view of a light emitting display device according to a second embodiment of the present disclosure. FIG. 10B is an enlarged plan view of an area C2 in FIG. 10A.

Referring to FIG. 10A, a plurality of emission areas EA are provided on a planarization layer 50, and reflective metals 270 surrounding the emission areas EA are provided. In accordance with the second embodiment, each reflective metal 270 can have a linear shape when viewed in plan view. The reflective metal 270 having the linear shape can surround at least one of a plurality of anodes 250. In addition, one reflective metal 270 surrounding one anode 250 and another reflective metal 270 surrounding another anode 250 can be interconnected through a connector, and the reflective metals 270 can be integrated with the connector. Of course, in the embodiment of the present disclosure, each of the reflective metals 270 surrounding the emission areas EA is configured to be disconnected at a portion thereof and, as such, the cathode 290, which is formed on the entire surface of a substrate, can supply a voltage to a plurality of emission areas EA.

In addition, referring to FIG. 10B, a bank 280 is provided on the planarization layer 50 while exposing the emission areas EA of the anodes 250 and the reflective metals 270. In addition, the bank 280 includes a trench T2 including a first trench T21 overlapping with the reflective metals 270, and a second trench T22 having a greater area than that of the first trench T21. The trench T2, which includes the first trench T21 and the second trench T22, is provided along the reflective metals 270 and the connector, to expose the reflective metals 270 and the connector. In detail, the first trench T21 is provided along peripheries of the reflective metals 270. In addition, the first trench T21 is configured to be disconnected around each anode 250 in accordance with a shape of each reflective metal 270 in which the reflective metal 270 is disconnected around each emission area EA. Under this condition, the cathode 290 formed on the entire surface of the substrate can apply a voltage to a plurality of emission areas EA. The second trench T22 is provided along the first trench T21 in a greater area than that of the first trench T21 while overlapping with the reflective metals 270.

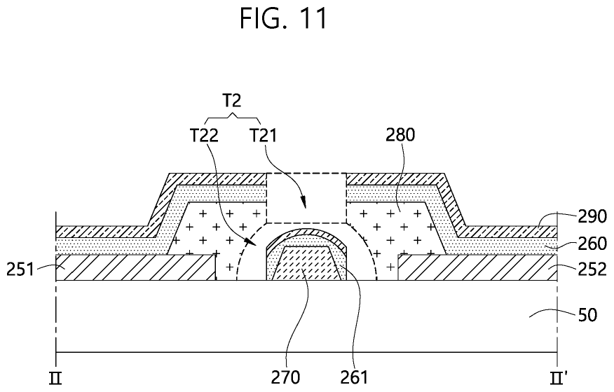

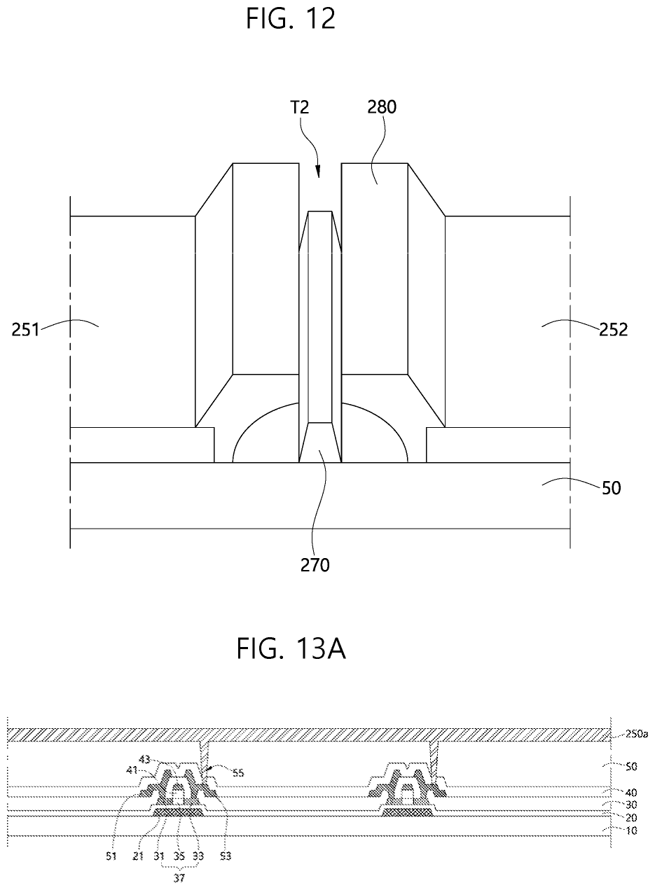

FIG. 11 is a cross-sectional view taken along line II-II′ in FIG. 10A. FIG. 12 is a perspective view corresponding to FIG. 11.

Referring to FIG. 11, in accordance with the second embodiment, a first anode 251 and a second anode 252 are disposed on the same layer as each reflective metal 270. In addition, the reflective metal 270 is provided between the first anode 251 and the second anode 252, and has a trapezoidal shape in which a top surface is smaller than a bottom surface.

The bank 280 includes the first trench T21 exposing the reflective metals 270 while overlapping with the reflective metals 270, and the second trench T22 disposed under the first trench T21 while spacing the inner surface of the bank 280 from upper surfaces of the reflective metals 270 by a predetermined distance. Since the second trench T22 is formed along the reflective metals 270 having the trapezoidal shape, the second trench T22 has an arch shape, similarly to the first embodiment.

Referring to FIG. 12, each reflective metal 270 according to the second embodiment of the present disclosure can have a straight shape. Accordingly, in the second embodiment of the present disclosure, it can be possible to more easily form the trench T2 of the bank 280 such that the trench T2 has an increased area, by virtue of the straight-shaped reflective metal 270. In addition, since the reflective metal 270 has a straight shape in accordance with the second embodiment of the present disclosure, it can be possible to more easily continuously form the trench T2, as compared to the trench T1 of the first embodiment.

The trench T2 of the bank 280 can also have an elongated tunnel shape along the straight-shaped reflective metal 270. In addition, similarly to the first embodiment, the trench T2 according to the second embodiment includes the first trench T21, which overlaps with the reflective metals 270, and the second trench T22, which overlaps with the first trench T21 and has a first distance d1 from the upper surface of each reflective metal 270. In addition, the cross-section of the second trench T22 can be formed to have a width gradually increasing while extending to a lower end of each reflective metal 270.

In the second embodiment of the present disclosure, the second trench T22 is configured to have an undercut shape under the first trench T21 and, as such, disconnection of an organic layer material at the trench T2 can be easily achieved. Thus, the organic layer material has a disconnected shape at the trench T2 and, as such, an organic layer 260 and an organic dummy pattern 261 are formed in a separated state over the bank 280 and the reflective metal 270, respectively.

In the second embodiment of the present disclosure, as each of the organic layer material and the cathode 290 is separated at the trench T2, and the organic layer material is separated into an organic layer 260 and an organic layer dummy pattern 261, an effect of preventing leakage current from flowing between the sub-pixels is provided.

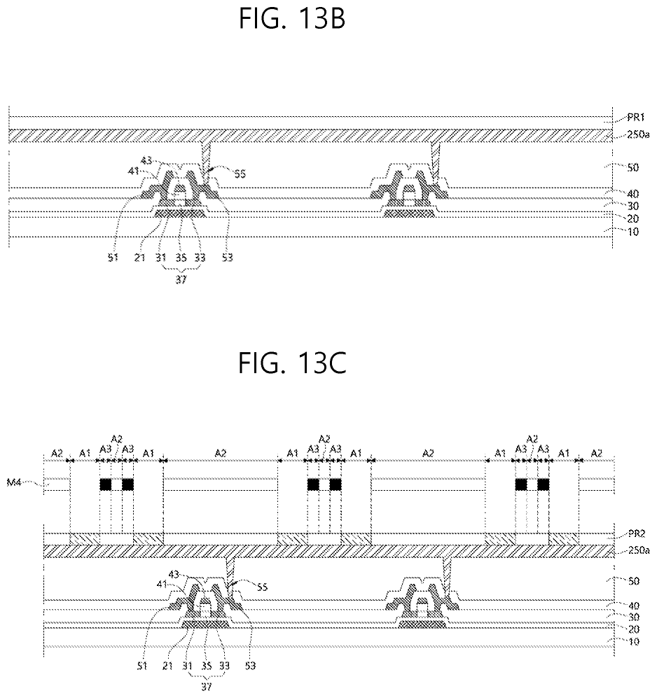

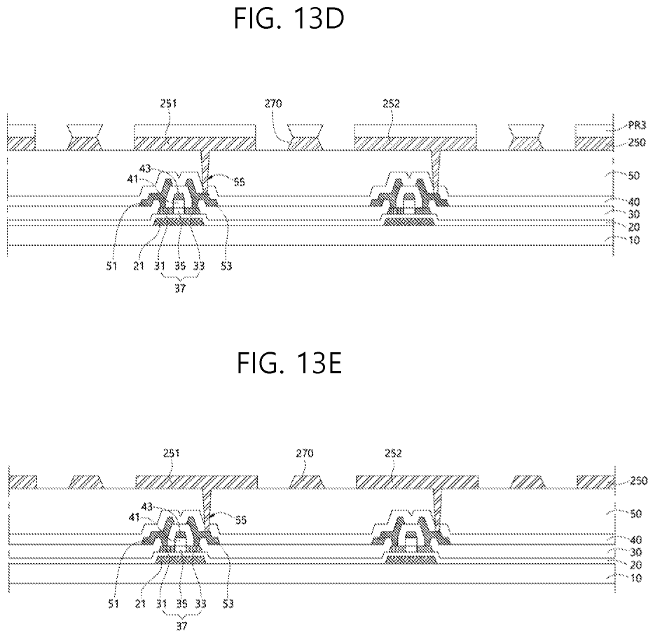

FIGS. 13A to 13E are cross-sectional views showing a method of manufacturing the reflective metal 270 of the light emitting display device according to the second embodiment of the present disclosure.

Referring to FIG. 13A, a thin film transistor TFT is formed on a substrate 10, and a light shielding layer 21, a buffer layer 20, an interlayer insulating layer 30, a protective layer 40, and a planarization layer 50 are sequentially formed on the substrate 10. A fourth metal material 250a is deposited over the entire surface of the planarization layer 50.

Thereafter, referring to FIG. 13B, a first photoresist material PR1 is deposited on the fourth metal material 250a. The deposited first photoresist material PR1 can be constituted by a photo-sensitive material such as a photoresist.

Subsequently, referring to FIG. 13C, light selectively irradiates the first photoresist material PR1 through a fourth mask M4, which is a half-tone mask according to the second embodiment of the present disclosure. As a result, a second photoresist material PR2, which has been selectively exposed to light, is formed.

Here, the fourth mask M4, which is a half-tone mask, includes a transmission area A1 configured to completely transmit irradiated light therethrough, a shielding area A2 configured to shield irradiated light, and a semi-transmission area A3 configured to transmit a portion of irradiated light therethrough. In this case, the semi-transmission area A3 is provided such that the reflective metal 370 is formed to have a trapezoidal shape.

Next, referring to FIG. 13D, the second photoresist material PR2 and the fourth metal material 250a are completely removed from the transmission area A1 through an etching process, and are partially removed in the semi-transmission area A3 such that the second photoresist material PR2 and the fourth metal material 250a have an inclined shape. As a result, the fourth metal material 250a is patterned into a plurality of anodes 250 including a first anode 251 and a second anode 252, and a reflective metal 270 between the first anode 251 and the second anode 252. Further, a third photoresist material PR3, which corresponds to the second photoresist material PR2 subjected to the etching process, is provided on the anodes 251, 252 and the reflective metal 270.

Subsequently, referring to FIG. 13E, the third photoresist material PR3, which corresponds to the second photoresist material PR2 subjected to the etching process, is removed and, as such, only the first anode 251, the second anode 252, and the reflective metal 270 remain on the planarization layer 50.

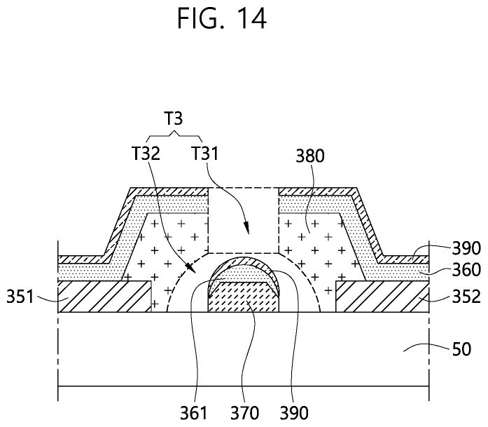

FIG. 14 is a cross-sectional view of a light emitting display device according to a third embodiment of the present disclosure.

Referring to FIG. 14, a reflective metal 370 can be provided between a first anode 351 and a second anode 352, and a bank 380 including a trench T3, which includes a first trench T31 and a second trench T32, can be provided in a non-emission area. An organic layer 360 and a cathode 390 can be provided on the bank 380.

In accordance with the third embodiment, the cross-section of the reflective metal 370 can have a hexagonal shape having a width gradually increasing as the cross-section extends downwards. In some cases, the reflective metal 370 can be formed to have an island shape, as in the first embodiment, can be formed to have a straight shape, as in the second embodiment, or can be formed to have both the above-described shapes. The reflective metal 370 according to the third embodiment can be formed to have a frustoconical or a frustum-of-pyramid shape having trapezoidal side surfaces, which is not proposed in the first to third embodiments. When a frustoconical or a frustum-of-pyramid reflective metal is formed, the bank can form a trench having a width gradually increasing as the trench extends to a lower end of the reflective metal.

In the third embodiment of the present disclosure, accordingly, the second trench T32 is configured to have an undercut shape under the first trench T32 and, as such, disconnection of an organic layer material at the trench T3 can be easily achieved. Thus, the organic layer material has a disconnected shape at the trench T3 and, as such, an organic layer 360 and an organic dummy pattern 361 are formed in a separated state over the bank 380 and the reflective metal 370, respectively.

In the third embodiment of the present disclosure, accordingly, as each of the organic layer material and the cathode 390 is separated at the trench T3, and the organic layer material is separated into an organic layer 360 and an organic layer dummy pattern 361, an effect of preventing leakage current from flowing between the sub-pixels is provided.

In accordance with the embodiments of the present disclosure, the reflective metal is provided in the non-emission area between the emission areas and, as such, a separate space for formation of the reflective metal is not required. In addition, the reflective metal is formed to have a size corresponding to 1/40 to 1/20 times a size of the anode. As described above, in accordance with the embodiments of the present disclosure, it can be possible to form a trench having a small size through irradiation of a laser onto the small-size reflective metal, as compared to the case in which a trench is formed using a mask. In the embodiments of the present disclosure, accordingly, it can be possible to disconnect the organic layer by the small-size trench and, as such, the area of the trench occupying the non-emission area is reduced. As a result, there is an effect of achieving high resolution without limiting the emission areas.

In conventional cases, the number of trenches at the bank is increased in order to prevent leakage current from flowing between sub-pixels. However, there can be a disadvantage in that it may be challenging to achieve high resolution because the area of trenches occupying the bank is increased due to the increased number of trenches.

In accordance with the embodiments of the present disclosure, a trench of the bank is formed as an arch-shaped undercut having a very small size, differently from the conventional cases. Accordingly, it can be possible to effectively disconnect an organic layer, even though the distance between the sub-pixels is small. As a result, there is an effect of achieving high resolution.

In addition, in conventional cases, a specific structure is formed on the bank in order to prevent flow of leakage current between sub-pixels. However, there can be a disadvantage in that a weak area may be generated between the structure and the bank due to shrinkage of the structure, which can damage the resultant device.

In display devices according to the embodiments of the present disclosure, however, an inner layer is deposited such that the inner layer is disposed in the bank, in place of the structure on the bank and, as such, a limitation such as a variation in inclination caused by shrinkage of the structure or formation of an area, on which a damage between the structure and the bank may be concentrated, can be reduced. Accordingly, there is an effect of increasing the lifespan of the resultant device.

In addition, in the display devices according to the embodiments of the present disclosure, light advancing to a side portion of the organic layer is refracted upwards by the reflective metal within the bank. Accordingly, there is an effect of enhancing a viewing angle and luminous efficacy.

In the light emitting display device according to each of the embodiments of the present disclosure, the following effects are provided.

First, the organic layer is separated in the non-emission area and, as such, there is an effect of preventing leakage current from flowing between two adjacent anodes.

Second, light advancing to the inside of the bank after being emitted from the organic layer is refracted upwards by the reflective metal within the bank and, as such, there is an effect of enhancing a viewing angle and luminous efficacy.

Third, a trench is formed at the bank using the reflective metal and a laser and, as such, there is an effect of achieving high resolution without limiting the emission area.

The light emitting display device according to one embodiment of the present disclosure is described as follows.

The light emitting display device according to one embodiment of the present disclosure can include a first anode and a second anode spaced apart from each other, a reflective metal between the first anode and the second anode, and a bank above the reflective metal at a non-emission area, to expose an emission area of each of the first anode and the second anode, the bank comprising a trench having a width gradually increasing while extending downwards toward the reflective metal.

In the light emitting display device according to one embodiment of the present disclosure, the trench comprises a first trench exposing the reflective metal, the first trench overlapping with the reflective metal, and a second trench disposed under the first trench, the second trench spacing an inner surface of the bank from an upper surface of the reflective metal by a first distance.

In the light emitting display device according to one embodiment of the present disclosure, the inner surface of the bank has an arch shape in cross-section.

In the light emitting display device according to one embodiment of the present disclosure, the reflective metal has an area gradually increasing as the reflective metal extends downwards.

In the light emitting display device according to one embodiment of the present disclosure, an upper surface of the reflective metal is curved or rounded in cross-section.

In the light emitting display device according to one embodiment of the present disclosure, the reflective metal has a shape surrounding at least one of the first anode or the second anode.

In the light emitting display device according to one embodiment of the present disclosure, the reflective metal comprises a reflective metal surrounding the first anode and a reflective metal surrounding the second anode, the reflective metal surrounding the first anode and the reflective metal surrounding the second anode being interconnected by a connector, and the reflective metals are integrated with the connector.

In the light emitting display device according to one embodiment of the present disclosure, the trench extends along the reflective metals and the connector, and exposes the reflective metals and the connector.

In the light emitting display device according to one embodiment of the present disclosure, the reflective metal is a same layer as the first anode and the second anode.

In the light emitting display device according to one embodiment of the present disclosure, the reflective metal comprises at least one of materials constituting the first anode and the second anode.

In the light emitting display device according to one embodiment of the present disclosure, the first trench has a width corresponding to a maximum width of the reflective metal.

In the light emitting display device according to one embodiment of the present disclosure, the reflective metal comprises at least one of aluminum (Al), silver (Ag), or titanium (Ti).

In the light emitting display device according to one embodiment of the present disclosure, the reflective metal is provided in plural, wherein the plural reflective metals are spaced apart from one another between the first anode and the second anode.

In the light emitting display device according to one embodiment of the present disclosure, an organic layer on the first anode, the second anode, and the bank, and an organic layer dummy pattern separated from the organic layer on the reflective metal at the trench.

Although the foregoing description has been given mainly in conjunction with embodiments, these embodiments are only illustrative without limiting the disclosure. Those skilled in the art to which the present disclosure pertains can appreciate that various modifications and applications illustrated in the foregoing description can be possible without changing essential characteristics of the embodiments. Therefore, the above-described embodiments should be understood as exemplary rather than limiting in all aspects. In addition, the scope of the present disclosure should also be interpreted by the claims below rather than the above detailed description. All modifications or alterations as would be derived from the equivalent concept intended to be included within the scope of the present disclosure should also be interpreted as falling within the scope of the disclosure.

What is claimed is:

1. A light emitting display device comprising:
a first anode and a second anode spaced apart from each other on a substrate;
a reflective metal between the first anode and the second anode; and
a bank above the reflective metal at a non-emission area to expose an emission area of each of the first anode and the second anode, the bank comprising a trench having a width gradually increasing while extending downwards toward the reflective metal.

2. The light emitting display device according to claim 1, wherein the trench comprises:
a first trench exposing the reflective metal, the first trench overlapping with the reflective metal; and
a second trench disposed under the first trench, the second trench forming a space extending from an upper surface of the reflective metal to an inner surface of the bank by a first distance.

3. The light emitting display device according to claim 2, wherein the inner surface of the bank has an arch shape in cross-section.

4. The light emitting display device according to claim 1, wherein the reflective metal has an area gradually increasing as the reflective metal extends downwards.

5. The light emitting display device according to claim 1, wherein the upper surface of the reflective metal is curved or rounded in cross-section.

6. The light emitting display device according to claim 1, wherein the reflective metal has a shape surrounding at least one of the first anode or the second anode.

7. The light emitting display device according to claim 6, wherein:
the reflective metal comprises a reflective metal surrounding the first anode and a reflective metal surrounding the second anode, the reflective metal surrounding the first anode and the reflective metal surrounding the second anode being interconnected by a connector; and
the reflective metals are integrated with the connector.

8. The light emitting display device according to claim 7, wherein the trench extends along the reflective metals and the connector, and exposes the reflective metals and the connector.

9. The light emitting display device according to claim 1, wherein the reflective metal is a same layer as the first anode and the second anode.

10. The light emitting display device according to claim 1, wherein the reflective metal comprises at least one of materials constituting the first anode and the second anode.

11. The light emitting display device according to claim 2, wherein the first trench has a width corresponding to a maximum width of the reflective metal.

12. The light emitting display device according to claim 1, wherein the reflective metal comprises at least one of aluminum (Al), silver (Ag), or titanium (Ti).

13. The light emitting display device according to claim 1, wherein the reflective metal is provided in plural, and the plural reflective metals are spaced apart from one another between the first anode and the second anode.

14. The light emitting display device according to claim 1, further comprising:
an organic layer on the first anode, the second anode, and the bank; and
an organic layer dummy pattern separated from the organic layer on the reflective metal at the trench.

15. The light emitting display device according to claim 1, wherein the reflective metal is formed to have an island shape.

16. The light emitting display device according to claim 1, wherein the reflective metal is formed to have a straight shape.

17. The light emitting display device according to claim 1, wherein the reflective metal is formed to have a frustoconical or a frustum-of-pyramid shape having trapezoidal side surfaces.

18. A method of manufacturing a light emitting display device, the method comprising:
a first step of forming a plurality of anodes spaced apart from one another on a substrate, and forming a reflective metal among the anodes that are spaced apart; and
a second step of forming a bank disposed above the reflective metal in a non-emission area to expose an emission area of each of the anodes, the bank comprising a trench having a width gradually increasing while extending downwards toward the reflective metal.

19. The method according to claim 18, wherein the first step comprises:
forming, on the substrate, a pattern definition part comprising a plurality of first openings and a second opening disposed among the first openings while having a smaller size than a size of each of the first openings; and
depositing a first metal material on the substrate, thereby respectively forming the anodes at the first openings on the substrate, and forming the reflective metal at the second opening so that the reflective metal has a curved surface.

20. The method according to claim 18, wherein the first step comprises:
forming, on the substrate, a pattern definition part comprising a plurality of first openings and a second opening disposed among the first openings while having a smaller size than a size of each of the first openings, using a first mask;
depositing a second metal material using a second mask, thereby respectively forming the anodes at the first openings on the substrate; and
depositing a third metal material using a third mask, thereby forming the reflective metal at the second opening on the substrate so that the reflective metal has a curved surface.

21. The method according to claim 18, wherein the second step comprises:
forming a bank material in the non-emission area;
primarily removing the bank material by a first width overlapping with the reflective metal, thereby forming a first trench exposing the reflective metal; and
secondarily removing the bank material around the reflective metal, thereby forming, under the first trench, the bank comprising a second trench disposed inside the bank,
wherein the second trench is defined as an inner surface of the bank, and the inner surface of the bank is spaced apart from an upper surface of the reflective metal by a first distance.

22. The method according to claim 21, wherein the forming the second trench comprises irradiating a laser onto the reflective metal, thereby forming the second trench in the bank through reflection of the laser from the reflective metal.

23. The method according to claim 21, wherein the forming the first trench comprises drilling the bank material, thereby forming the first trench in the bank.

24. The method according to claim 18, further comprising:
forming an organic layer on the plurality of anodes and the bank; and
forming an organic layer dummy pattern separated from the organic layer on the reflective metal at the trench.
